(19) United States
(12) Patent Application Publication
(10) Pub. No.: US 2025/0386595 A1
(43) Pub. Date: Dec. 18, 2025

(54) CFET TYPE TRANSISTOR DEVICE

(71) Applicant: Commissariat à l'Énergie Atomique et aux Énergies Alternatives, Paris (FR)

(72) Inventor: Sylvain Barraud, Grenoble (FR)

(73) Assignee: Commissariat á l'Énergie Atomique et aux Énergies Alternatives, Paris (FR)

(21) Appl. No.: 19/240,325

(22) Filed: Jun. 17, 2025

(30) Foreign Application Priority Data
Jun. 18, 2024 (FR) FR2406481

(51) Int. Cl. H10D 84/85; H10D 30/00; H10D 30/01; H10D 30/43; H10D 62/10; H10D 62/13; H10D 62/40; H10D 64/01; H10D 84/01

(52) U.S. Cl. CPC H10D 84/851; H10D 30/014; H10D 30/0191; H10D 30/43; H10D 30/502; H10D 62/121; H10D 62/151; H10D 62/405; H10D 64/017; H10D 84/017; H10D 84/0177; H10D 84/0184; H10D 84/856

(57) ABSTRACT

A CFET transistor device, including: a substrate; a first semiconductor nanosheet and a second semiconductor nanosheet; an insulating layer arranged between the first and second nanosheets; a first gate arranged around a first part of the first nanosheet, and a second gate arranged around a first part of the second nanosheet; first inner spacers arranged against second parts of the first nanosheet, between which the first part of the first nanosheet is arranged, and second inner spacers arranged against second parts of the second nanosheet between which the first part is arranged; and wherein the first and second inner spacers respectively include first and second low-permittivity dielectric materials different from each other.

### CROSS REFERENCE TO RELATED APPLICATIONS

This application claims priority to French application number FR2406481, filed Jun. 18, 2024. The contents of this application is incorporated by reference in its entirety.

### TECHNICAL FIELD

The present disclosure generally concerns the field of devices with complementary field-effect transistors (CFET).

### PRIOR ART

A CFET transistor device comprises N- and P-type FET transistors stacked one on top of the other, or on top of one another, and having their channels formed of stacked semiconductor nanosheets. The gates of these transistors surround the portions of the semiconductor nanosheets which form the transistor channels, similarly to GAA (Gate-All Around) transistors.

Such CFET transistor devices are, for example, formed from a stack of layers comprising an alternation of first and second layers of materials that can be selectively etched with respect to one another, for example first silicon layers and second SiGe layers. An insulating layer is arranged between those intended to form part of the N-type transistor(s) and those intended to form part of the P-type transistor(s). A selective etching is implemented such that remaining portions of the first or of the second layers are intended to form the transistor channels, as well as interface regions, or LDD (Lightly Doped Drain) and LDS (Lightly Doped Source) regions, intended to be arranged between the channels and the source or drain regions which are subsequently formed. In such transistors, inner spacers are formed around these interface regions. Such transistors are described, for example, in documents US 2021/265345 A1 and US 2022/020646 A1.

The structures of the above-described CFET transistor devices however have the disadvantage that N-type and P-type transistors have channels comprising a same semiconductor material. Further, in these structures, the electrostatic properties of P-type transistors are necessarily similar to those of N-type transistors, given the method implemented for their forming. Finally, both N-type and P-type transistors also have the same crystallographic orientation, which does not enable to optimize both electron transport for the N-type transistor and hole transport for the P-type transistor.

### SUMMARY OF THE INVENTION

There exists a need to provide a device with CFET transistors which does not have at least part of the above disadvantages, and in particular enabling to dissociate the electrical and/or electrostatic properties of N-type transistor(s) from those of P-type transistor(s).

An embodiment overcomes all or part of these disadvantages and provides a device with complementary field-effect transistors, comprising:
a substrate;
at least one first semiconductor nanosheet and at least one second semiconductor nanosheet, the first semiconductor nanosheet being arranged between the second semiconductor nanosheet and the substrate;
an insulating layer between the first and second semiconductor nanosheets;
a first gate arranged around a first part of the first semiconductor nanosheet, and a second gate arranged around a first part of the second semiconductor nanosheet;
first inner spacers arranged against second parts of the first semiconductor nanosheet, between which the first part of the first semiconductor nanosheet is arranged, and
second inner spacers arranged against second parts of the second semiconductor nanosheet, between which the first part of the second semiconductor nanosheet is arranged;
and wherein the first and second inner spacers respectively comprise first and second low-permittivity dielectric materials, the first and second dielectric materials being different from each other.

According to a specific embodiment, the insulating layer is arranged opposite, or vertically in line with, all the surfaces of the first and second semiconductor nanosheets located, or oriented, opposite the insulating layer.

According to a specific embodiment, the first and second semiconductor nanosheets respectively comprise first and second semiconductor materials different from each other.

According to a specific embodiment, the first and second semiconductor nanosheets respectively comprise first and second semiconductor materials having crystalline orientations, or crystallographic orientations, different from each other.

According to a specific embodiment, the first and second gates respectively comprise first and second metallic materials different from each other.

According to a specific embodiment, at least part of the first gate is in contact with at least part of the second gate, or the first and second gates are dissociated and insulated from each other.

According to a specific embodiment, when the first and second gates are dissociated and insulated from each other, each of the first and second gates is comb-shaped.

There is also provided a method of manufacturing a device with complementary field-effect transistors, comprising at least:
the forming of a structure comprising at least one substrate, first and second semiconductor nanosheets, the first semiconductor nanosheet being arranged between the second semiconductor nanosheet and the substrate, and an insulating layer arranged between the first and second semiconductor nanosheets;
the forming of first inner spacers arranged against second parts of the first semiconductor nanosheet, and of second inner spacers arranged against second parts of the second semiconductor nanosheet, the first and second inner spacers respectively comprising first and second low-permittivity dielectric materials, the first and second dielectric materials being different from each other, and such that the first inner spacers are formed before or after the second inner spacers;
the forming of a first gate around a first part of the first semiconductor nanosheet arranged between the second parts of the first semiconductor nanosheet, and of a second gate around a first part of the second semiconductor nanosheet arranged between the second parts of the second semiconductor nanosheet.

According to a specific embodiment, the embodiment of the structure comprises at least:
the forming of a first stack of layers comprising at least one first semiconductor layer arranged between two first sacrificial layers made of a material capable of being selectively etched over the first semiconductor layer, and comprising a first dielectric layer;
the forming of a second stack of layers comprising at least one second semiconductor layer arranged between two second sacrificial layers of a material capable of being selectively etched over the second semiconductor layer, and comprising a second dielectric layer;
bonding of the first and second dielectric layers to each other and forming together the insulating layer.

According to a specific embodiment, at the end of these steps, the insulating layer is arranged opposite all the surfaces of the first and second semiconductor nanosheets located opposite the insulating layer.

According to a specific embodiment, the forming of the structure further comprises, after the bonding of the first and second dielectric layers to each other, an etching of at least one trench implemented through the first and second stacks of layers and the insulating layer.

According to a specific embodiment, the forming of the second inner spacers comprises at least:
the forming of a sacrificial gate in the trench and on the remaining portions of the structure obtained at the end of the etching of the trench, then
the forming of gate spacers around the sacrificial gate, then
the etching of parts of the remaining portions of the structure not covered by the sacrificial gate and the gate spacers, through the layers of the second stack and a first part of the insulating layer without crossing a bonding interface between the first and second dielectric layers, then
the etching of parts of remaining portions of the second sacrificial layers against the second parts of the second semiconductor nanosheet, then
the forming of a layer of the second low-permittivity dielectric material such that portions of this layer arranged against second parts of the second semiconductor nanosheet form the second inner spacers.

According to a specific embodiment, the forming of the first inner spacers comprises at least, after the forming of the layer of the second low-permittivity dielectric material:
the etching of parts of the remaining portions of the structure not covered by the sacrificial gate, the gate spacers, and by parts of the layer of the second low-permittivity dielectric material which rest on a second part of the insulating layer comprising the bonding interface and which cover ends of the second parts of the second semiconductor nanosheet, through the layers of the first stack and the second part of the insulating layer, then
the etching of parts of remaining portions of the first sacrificial layers arranged against the second parts of the first semiconductor nanosheet, then
the forming of a layer of the first low-permittivity dielectric material such that portions of this layer arranged against second parts of the first semiconductor nanosheet form the first inner spacers.

According to a specific embodiment, the method further comprises, between the forming of the first and second inner spacers and the forming of the first and second gates:
the forming of first source or drain regions against ends of the second parts of the first semiconductor nanosheet, then
the removal of the parts of the layer of the second low-permittivity dielectric material covering the ends of the second parts of the second semiconductor nanosheet, then
the forming of second source or drain regions against ends of second parts of the second semiconductor nanosheet.

According to a specific embodiment, the embodiments of the first and second source or drain regions each comprise the implementation of an epitaxy, and the method further comprises, between the forming of the first and second source or drain regions, a deposition of an insulating material covering at least the first source and drain regions.

According to a specific embodiment, the method further comprises, between the forming of the first and second inner spacers and the forming of the first and second gates or during the forming of the first and second gates, an etching of the remaining portions of the first and second sacrificial layers.

According to a specific embodiment, the forming of the first and second gates comprises an etching of the sacrificial gate, and then successive depositions of at least one first metallic material forming the first gate and of at least one second metallic material different from the first metallic material and forming the second gate, and such that at least part of the first gate is in contact with at least part of the second gate.

According to a specific embodiment, the forming of the first and second gates comprises:
an etching of a first part of the sacrificial gate so as to form an access to the first part of the second semiconductor nanosheet, then
a deposition of materials forming the second gate, then
an etching of a second part of the sacrificial gate so as to form an access to the first part of the first semiconductor nanosheet, then
a deposition of materials forming the first gate such that the first and second gates are dissociated and insulated from each other.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows a perspective and cross-section view of a CFET transistor device according to a first embodiment;

FIG. 2 schematically shows a perspective and cross-section view of a CFET transistor device according to a second embodiment;

FIG. 3, FIG. 4, FIG. 5, FIG. 6, FIG. 7, FIG. 8, FIG. 9, FIG. 10, FIG. 11, FIG. 12, FIG. 13, FIG. 14, FIG. 15, FIG. 16, FIG. 17, FIG. 18, and FIG. 19 show steps of a method of manufacturing a CFET transistor device according to the first embodiment;

FIG. 20, FIG. 21, FIG. 22, and FIG. 23 show part of the steps of a method of manufacturing a CFET transistor device according to the second embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Throughout the document, the terms “conductive” and “insulating” are used to respectively designate electrical conduction and electrical insulation.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

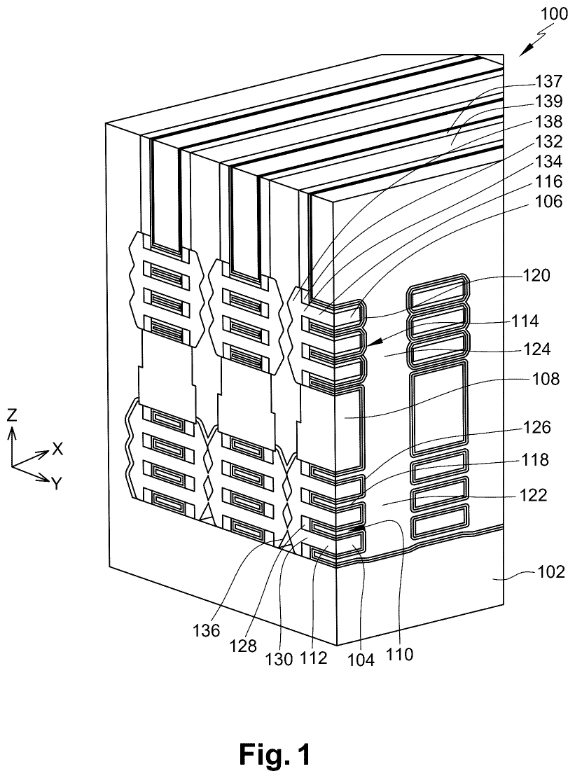

An example of embodiment of a device 100 with CFET transistors according to a first embodiment is described hereafter in relation with FIG. 1.

Device 100 comprises a substrate 102 on which the various parts and elements of device 100 are arranged. For example, the layer of substrate 102 on which the various parts and elements of device 100 are arranged may correspond to the buried dielectric layer, or BOX (“Buried Oxide”), of a substrate of semiconductor-on-insulator type, for example SOI (Silicon on Insulator), or an STI-type shallow trench isolation region formed, for example, in a bulk semiconductor substrate, for example made of silicon. As a variant, another type of substrate 102 may be used for the manufacturing of device 100.

Device 100 further comprises at least one first semiconductor nanosheet 104 and at least one second semiconductor nanosheet 106, such that the first semiconductor nanosheet 104 is arranged between the second semiconductor nanosheet 106 and substrate 102. In the example of FIG. 1, device 100 comprises a plurality of stacks of a plurality of first semiconductor nanosheets 104, above each of which a stack of a plurality of second semiconductor nanosheets 106 is arranged. In the example of FIG. 1, the stacks of the first and second semiconductor nanosheets 104, 106 are arranged, in a plane of the surface of substrate 102 on which the semiconductor nanosheet stacks 104, 106 are arranged, in rows (for example parallel to the X axis of FIG. 1) and columns (for example parallel to the Y axis of FIG. 1).

According to an example of embodiment, the first and second semiconductor nanosheets 104, 106 respectively comprise first and second semiconductors different from each other. For example, the first semiconductor may be silicon, and the second semiconductor may be SiGe. The first and second semiconductor nanosheets 104, 106 may, however, comprise other examples of semiconductors, such as for example Ge, GeSn, or semiconductor oxides (IGZO, IWO, ITO, etc.) or other III-V materials (InAS, InGaAs, for example). According to another example of embodiment, the first and second semiconductor nanosheets 104, 106 comprise identical first and second semiconductors.

In a specific configuration, the crystalline orientations of the first and second semiconductors may be different from each other. For example, when the first semiconductor of the first semiconductor nanosheets 104 is intended to form the channel of at least one NFET transistor, its crystalline orientation may be achieved along the (100) plane and the direction, which enables to favor electron transport in this first semiconductor. When the second semiconductor of the second semiconductor nanosheets 106 is intended to form a PFET transistor, its crystalline orientation may be achieved along the (110) plane and the direction, which enables to favor hole transport in this second semiconductor.

According to an embodiment, the thickness (dimension parallel to the Z axis in the example of FIG. 1) of each of the first and second semiconductor nanosheets 104, 106 may be in the range from 5 nm to 20 nm. Further, the length (dimension parallel to the Y axis in the example in FIG. 1) of each of the first and second semiconductor nanosheets 104, 106 may be in the range from 15 nm to 50 nm. Finally, the width (dimension parallel to the X axis in the example of FIG. 1) of each of the first and second semiconductor nanosheets 104, 106 may be in the range from 10 nm to 150 nm.

Device 100 further comprises an insulating layer 108 arranged between the first and second semiconductor nanosheets 104, 106. In the example of FIG. 1, insulating layer 108 is arranged between the stacks of the first semiconductor nanosheets 104 and the stacks of the second semiconductor nanosheets 106. According to an embodiment, insulating layer 108 may comprise SiO₂ and have a thickness (dimension parallel to the Z axis in the example of FIG. 1) for example in the range from 10 nm to 100 nm. As a variant, insulating layer 108 may comprise other examples of dielectric material and/or a thickness different from that indicated hereabove.

Further, in the described example, insulating layer 108 is arranged opposite, or vertically in line with, all the surfaces of the first and second semiconductor nanosheets 104, 106 oriented, or located, opposite insulating layer 108. In other words, a projection of the surfaces of the first and second semiconductor nanosheets 104, 106 onto the surfaces of insulating layer 108 arranged opposite thereto is equal to or included in said surfaces of insulating layer 108. Thus, insulating layer 108 extends over or under the entire surface of semiconductor nanosheets 104, 106. Further, in the described example, side edges of the insulating layer 108 are arranged in line with side edges of the nanosheets.

Device 100 also comprises a first gate 110 arranged around a first portion 112 of the first semiconductor nanosheet 104, and a second gate 114 arranged around a first portion 116 of the second semiconductor nanosheet 106. In the example shown in FIG. 1, the first gate 110 is arranged around first portions 112 of each of the first semiconductor nanosheets 104, and the second gate 114 is arranged around first portions 116 of each of the second semiconductor nanosheets 106. The first parts 112, 116 of the first and second semiconductor nanosheets 104, 106 form the channels of the transistor or transistors of device 100. The first and second gates 110, 114 can be seen as forming at least semi-around gates.

In the described embodiment, the first and second gates 110, 114 respectively comprise first and second metallic materials 118, 120, which are different in nature from each other. In the first described embodiment, the first and second metallic materials 118, 120 are such that they have a value of the work function different from each other.

In the example of FIG. 1, parts 122 of the first gate 110 are in contact with parts 124 of the second gate 114, these parts 122, 124 being used to electrically access gates 110, 114. In the example of FIG. 1, these parts 122, 124 are located between the rows and the columns of stacks of the first and second semiconductor nanosheets 104, 106. In this example, due to the fact that the portions 122, 124 of gates 110, 114 are in contact with each other, they form a common gate for the transistors of device 100. The first and second metallic materials 118, 120 may respectively comprise TiN and W, or any other suitable material such as at least one of the following materials: Al, Ni, Ti, TaN, TIC, TaC, etc.

In the example of FIG. 1, the first and second gates 110, 114 also comprise a gate dielectric 126 interposed between the first and second metallic materials 118, 120 and the other elements of device 100. In the described embodiment, gate dielectric 126 is common to the first and second gates 110, 114. As a variant, the gate dielectric of the first gate 110 could be formed by separate portions, non-continuous with respect to those of the gate dielectric of the second gate 114. For example, gate dielectric 126 may comprise a high-permittivity dielectric material such as HfSiO₄, HfO₂, La₂O₃, LaALO₃, ZrO₂, ZrSiO₄, Ta₂O₅, TiO₂, SrTiO₃, Al₂O₃. A high-k dielectric material may correspond to a dielectric material having a dielectric permittivity greater than that of SiO₂, for example greater than 3.9.

Device 100 also comprises first inner spacers 128 arranged against second parts 130 of the first semiconductor nanosheet 104 (of each of the first semiconductor nanosheets 104 in the example of FIG. 1), between which the first part 112 of the first semiconductor nanosheet 104 (of each of the first semiconductor nanosheets 104 in the example of FIG. 1) is arranged. Device 100 further comprises second inner spacers 132 arranged against second parts 134 of the second semiconductor nanosheet 106 (of each of the second semiconductor nanosheets 106 in the example of FIG. 1), between which the first part 116 of the second semiconductor nanosheet 106 (of each of the first semiconductor nanosheets 106 in the example of FIG. 1) is arranged. In the example of FIG. 1, the first and second parts 112, 130 of each first semiconductor nanosheet 104 and the first and second parts 116, 134 of each second semiconductor nanosheet 106 are symbolically separated by dotted lines. Further, in the example of FIG. 1, first inner spacers 128 are arranged around the second parts 130 of each of the first semiconductor nanosheets 104, and the second inner spacers 132 are arranged around the second parts 134 of each of the second semiconductor nanosheets 106.

In the described example, insulating layer 108 is arranged opposite all the surfaces of the first and second semiconductor nanosheets 104, 106 oriented, or located, opposite insulating layer 108, that is, the surfaces of the first parts 112, 116 and of the second parts 130, 134 of the first and second semiconductor nanosheets 104, 106. The edges of the insulating layer are aligned with the edges of the nanosheets.

The first and second inner spacers 128, 132 respectively comprise different first and second low-k dielectric materials, that is, dielectric materials having a permittivity smaller than or equal to that of silicon nitride. For example, inner spacers 128, 132 may comprise at least one of the following materials: SiN, SiOCN, SiBCN, SiOC, SiCN, SiO₂. The use of such low-permittivity dielectric materials for the forming of inner spacers 128, 132 has the advantage of decreasing the parasitic capacitances of the transistors of device 100.

In the example of FIG. 1, device 100 also comprises first source or drain regions 136 extending from the ends of the second parts 130 of the first semiconductor nanosheets 104, and second source or drain regions 138 extending from ends of the second parts 134 of the second semiconductor nanosheets 106. For example, the first or second source or drain regions 136, 138 may comprise phosphorus-doped silicon when they are intended to form part of an N-type transistor, or may comprise boron-doped SiGe when they are intended to form part of a P-type transistor.

In the example of FIG. 1, device 100 also comprises gate spacers 137, as well as insulating material 139 arranged between the rows of stacks of semiconductor nanosheets 104, 106. Inner spacers 128, 132 are arranged vertically in line with gate spacers 137. Gate spacers 137 may comprise a low-permittivity dielectric material, for example identical to or different from that of inner spacers 128, 132, thus contributing to the decrease of the parasitic capacitances of the transistors of device 100. According to an example, insulating material 139 may comprise a dielectric material such as SiO₂ or SiN.

In the example of FIG. 1, the first semiconductor nanosheets 104, the first gate 110, the first inner spacers 128, and the first source or drain regions 136 form at least one first FET transistor of a first conductivity type, for example an NFET transistor. Further, the second semiconductor nanosheets 106, the second gate 114, the second inner spacers 132, and the second source or drain regions 138 form at least one second FET transistor of a second conductivity type opposite to the first conductivity type, for example a PFET transistor.

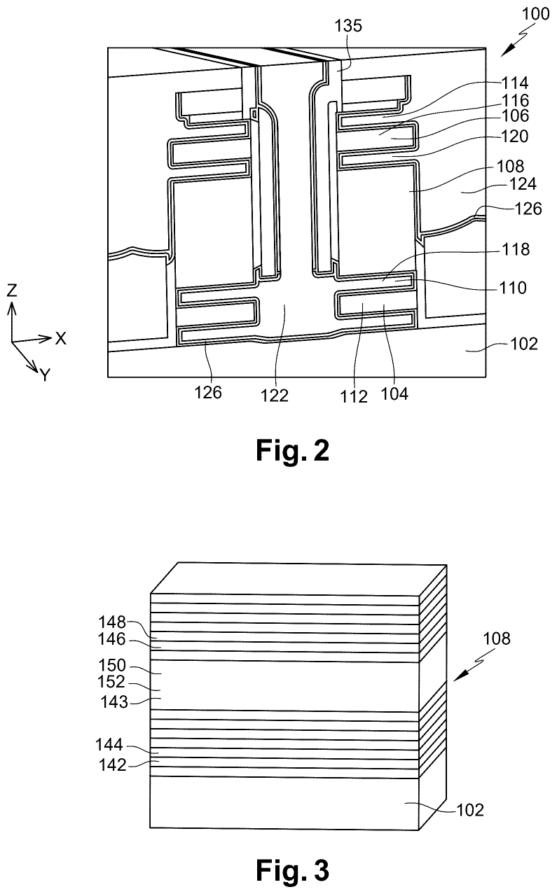

An example of embodiment of a device with CFET transistors 100 according to a second embodiment is described hereafter in relation with FIG. 2.

Conversely to the first embodiment, the first and second gates 110, 114 are dissociated and insulated from each other. In other words, the first and second gates 110, 114 are not in contact with each other. This dissociation and insulation are achieved by forming the parts 122, 124 used for the electric contact of these gates 110, 114 in different trenches formed between the rows or columns of the stacks of the semiconductor nanosheets 104, 106 (between the columns of the stacks of semiconductor nanosheets 104, 106 in the example of FIG. 2). In this configuration, insulating portions 135, comprising for example SiN or any other suitable dielectric material, enable to electrically insulate the part 122 of the first gate 110 from the second semiconductor nanosheets 106.

In this second embodiment, the first and second gates 110, 114 may be comb-shaped, as is the case in the example of FIG. 2, with semiconductor nanosheets 104, 106 arranged between the teeth of these combs. Further, in this configuration, for each transistor, one side of the channel is not covered by the gate 110, 114 of this transistor.

The other features and elements of the device 100 according to the second embodiment are similar or identical to those of the first embodiment.

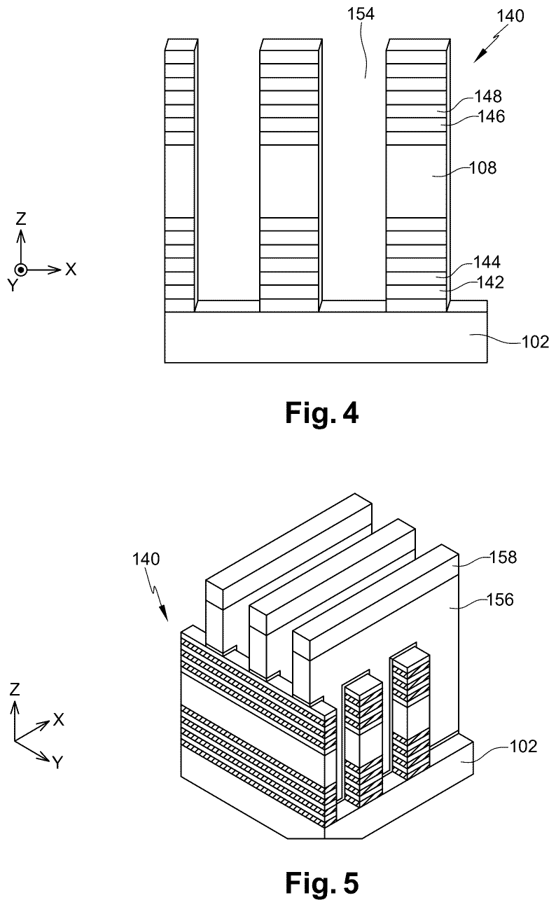

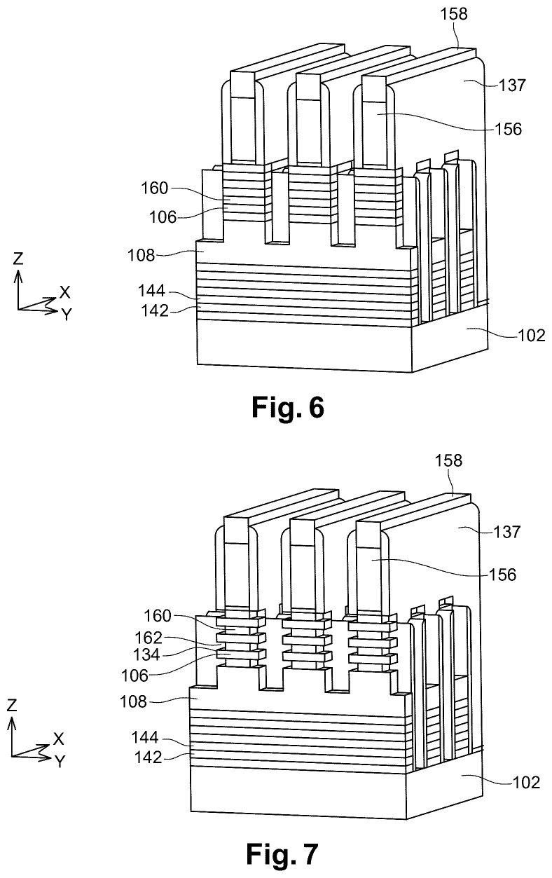

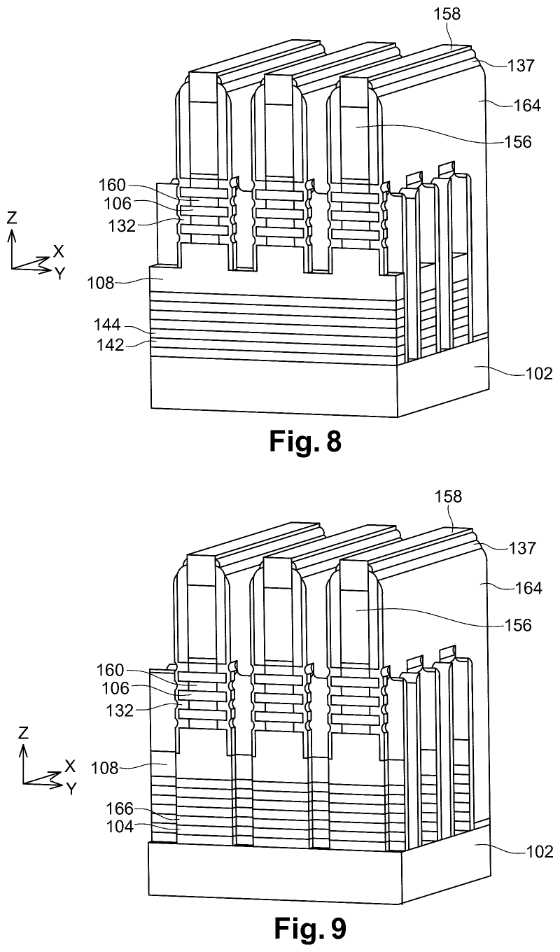

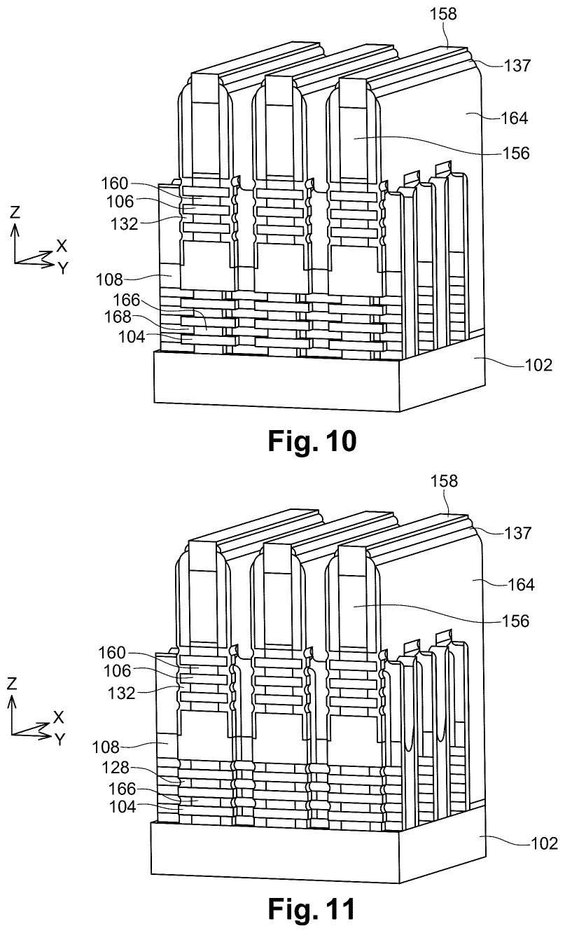

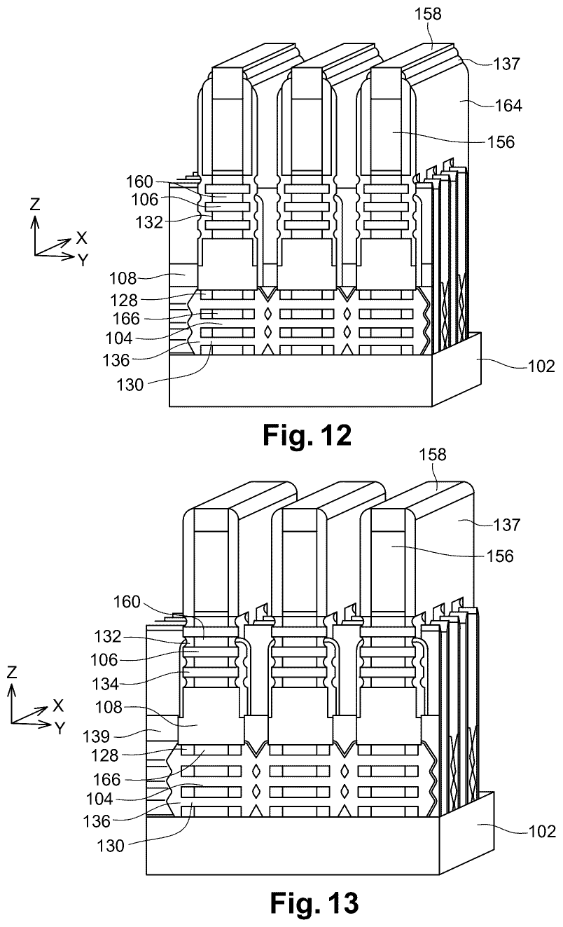

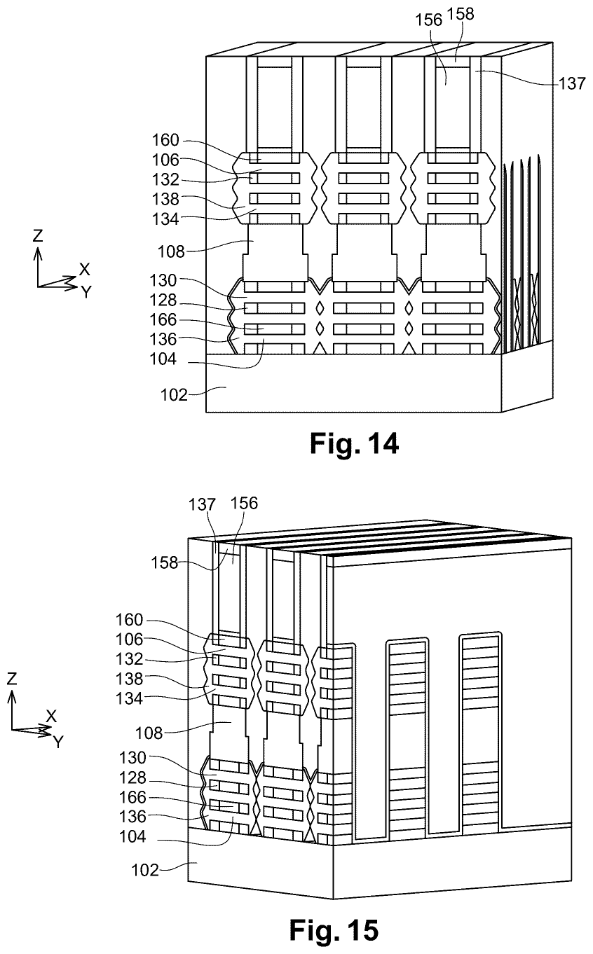

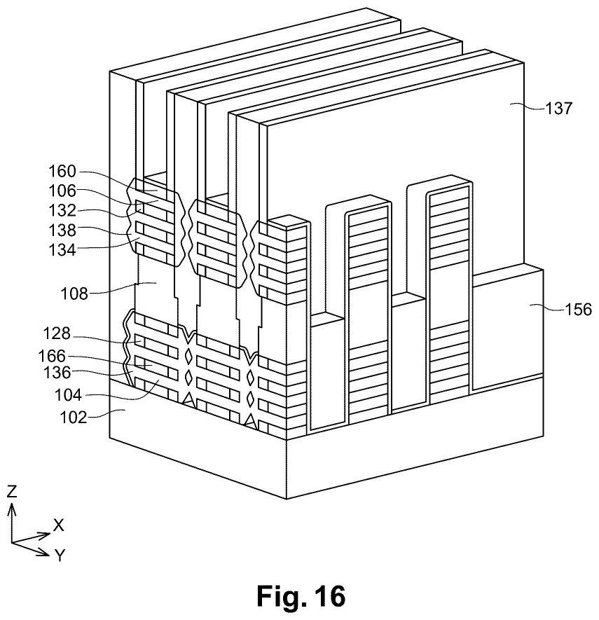

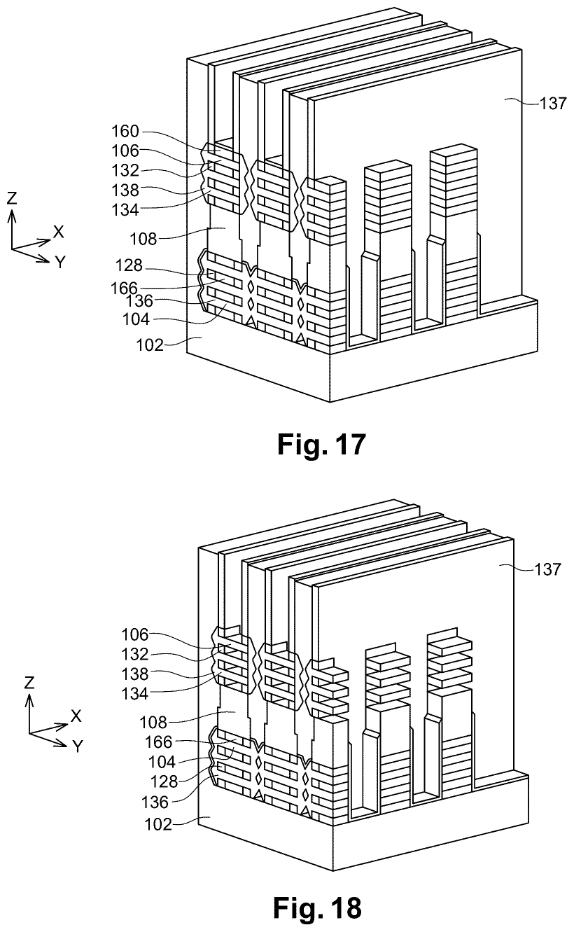

An example of a method of forming the device 100 according to the first embodiment is described hereafter in relation with FIGS. 3 to 19.

First, a structure 140 comprising at least substrate 102, the first and second semiconductor nanosheets 104, 106, and insulating layer 108 is formed.

This structure 140 can be obtained by first forming a first stack of layers comprising at least a first semiconductor layer 142 arranged between two first sacrificial layers 144 of a material capable of being selectively etched over that of the first semiconductor layer 142, the first stack also comprising a first dielectric layer 143. The first dielectric layer 143 comprises, for example, SiO₂ obtained by thermal oxidation. In the described example, given that device 100 is intended to comprise a plurality of stacked first semiconductor nanosheets 104, the first stack comprises a plurality of first semiconductor layers 142 based on which the first semiconductor nanosheets 104 are intended to be formed, each of the first semiconductor layers 142 being arranged between two first sacrificial layers 144. Further, in this example of embodiment, this first stack is formed on substrate 102 in such a way that the first semiconductor layers 142 and the first sacrificial layers 144 are arranged between substrate 102 and the first dielectric layer 143.

In this example, a second stack of layers comprising at least one second semiconductor layer 146 arranged between two second sacrificial layers 148 of a material capable of being selectively etched over that of the second semiconductor layer 146 is also formed, the second stack also comprising a second dielectric layer 150. The second dielectric layer 150 comprises, for example, SiO₂ obtained by thermal oxidation. In the described example, given that device 100 is intended to comprise a plurality of stacked second semiconductor nanosheets 106, the second stack comprises a plurality of second semiconductor layers 146 based on which the second semiconductor nanosheets 106 are intended to be formed, each of the second semiconductor layers 146 being arranged between two second sacrificial layers 148. According to an example, this second stack may be formed on another substrate such that the second semiconductor layers 146 and the second sacrificial layers 148 are arranged between this other substrate and the second dielectric layer 150.

According to a specific embodiment, the first sacrificial layers 144 may comprise SiGe, and the first semiconductor layers 142 may comprise silicon or SiGe with a lower germanium concentration than that of the SiGe of the first sacrificial layers 144. For example, the first sacrificial layers 144 may comprise Si_{0.7}Ge_{0.3} and the first semiconductor layers 142 may comprise Si. Further, the second sacrificial layers 148 may comprise SiGe, and the second semiconductor layers 146 may comprise silicon or SiGe with a lower germanium concentration than the SiGe of the second sacrificial layers 148. For example, the second sacrificial layers 148 may comprise Si_{0.4}Ge_{0.6} and the second semiconductor layers 146 may comprise Si_{0.7}Ge_{0.3}. These examples particularly enable to implement a selective etching of the first sacrificial layers 144 over the first semiconductor layers 142, and a selective etching of the second sacrificial layers 148 over the second semiconductor layers 146. As a variant, other materials capable of being selectively etched with respect to one another may be used for the layers of the first and second stacks.

In this specific embodiment of structure 140, a bonding of the first and second dielectric layers 143, 150 is then implemented in such a way that they form together insulating layer 108. The bonding interface between the first and second dielectric layers 143, 150 is designated with reference numeral 152. The substrate used for the forming of the second stack can then be removed, and substrate 102 is kept to be used as a support. The stack of layers obtained at this stage of the method is shown in FIG. 3.

The resulting stack of layers can then be etched to form trenches 154 through the stacks of layers 142, 144, 146, 148 and insulating layer 108 and delimit semiconductor nanosheets 104, 106 in a first direction (along the X axis in the described example). This etching is stopped on substrate 102. The resulting structure 140 is shown in FIG. 4.

The method then comprises the successive forming of the first and second inner spacers 128, 132. In the described example of embodiment, the second inner spacers 132 are formed before the first inner spacers 128.

To form the second inner spacers 132, a sacrificial gate 156 is first formed on the remaining portions of structure 140 obtained at the end of the etching implemented through the stacks of layers 142, 144, 146, 148 and insulating layer 108. For example, sacrificial gate 156 may be formed by implementing a first deposition of oxide, for example of SiO₂, followed by a deposition of polysilicon or amorphous silicon. These layers can then be etched according to the pattern desired for sacrificial gate 156. An etch mask 158 comprising, for example, SiN may be used for this etching. The assembly obtained at this stage of the method is shown in FIG. 5.

Gate spacers 137 can then be formed around sacrificial gate 156. The material deposited to form gate spacers 137 and which covers parts of the stack which are not intended to be covered by the gate spacers may be subsequently removed by etching, for example by implementing a dry etching such as an anisotropic plasma etching using at least one of the following gases: CF₄/O₂/N₂, CFA/CH₄, SF₆/CH₄, NF₃/CH₄. The remaining material then forms gate spacers 137.

In the described example of embodiment, an etching of parts of the remaining portions of the structure 140 not covered by sacrificial gate 156 and by gate spacers 137 may then be performed through the second semiconductor layers 146 and the second sacrificial layers 148 and a first part of the insulating layer 108 without crossing bonding interface 152. This etching enables to form, in particular, the second semiconductor nanosheets 106, each arranged between two remaining portions 160 of the second sacrificial layers 148. The fact for the etching not to be carried out through bonding interface 152 particularly avoids an exposure of this interface to the subsequently-used etching chemistries. The second semiconductor nanosheets 106 are arranged vertically in line with parts of insulating layer 108. The structure obtained at this stage of the method is shown in FIG. 6.

In the described example of embodiment, an etching of parts of the remaining portions 160 of the second sacrificial layers 148 arranged against the second parts 134 of the second semiconductor nanosheets 106 is then implemented. Further, this etching is here carried out in such a way that it is selective over the second semiconductor nanosheets 106. This etching forms cavities 162 in which the second inner spacers 132 will be subsequently formed. Further, the duration of implementation of this etching determines the lengths of the cavities 132 along the second semiconductor nanosheets 106, and also the length of the channel formed by these second semiconductor nanosheets 106. The structure obtained at this stage of the method is shown in FIG. 7.

In the described example of embodiment, a deposition of a layer 164 of the second low-permittivity dielectric material is implemented in such a way that portions of this layer 164 arranged against second parts 134 of the second semiconductor nanosheets 106, that is, in cavities 162, form the second inner spacers 132. Depending on the nature of the material deposited to form this layer 164, the implemented deposition may, for example, be of ALD (Atomic Layer Deposition), LPCVD (Low-Pressure Chemical Vapor Deposition), or PECVD (Plasma-Enhanced Chemical Vapor Deposition) type. The second, low-permittivity dielectric material of layer 164 may be identical to or different from that used to form gate spacers 137.

An anisotropic etching can then be implemented to remove parts of layer 164 deposited on insulating layer 108. This etching corresponds, for example, to a dry etching implemented by using for example a gas mixture of CH₂F₂/O₂/CH₄/Ar type or a plasma of CH₃F/O₂/He type. As a variant, it is possible to perform an anisotropic modification of layer 164 with a plasma of H₂ or He type, followed by a wet etching implemented by using, for example, hydrofluoric acid or Hf in vapor form, or a plasma of NH₃/NF₃ type. It is also possible to implement a second isotropic etching so as to decrease the thickness of layer 164, for example, a wet etching using a dilute solution of hydrofluoric acid or hot phosphoric acid, this second isotropic etch being carried out without exposing the second semiconductor nanosheets 106.

The structure obtained at this stage of the method is shown in FIG. 8.

The first inner spacers 128 are then formed. For this purpose, in the described example of embodiment, an etching of parts of the remaining portions of the structure not covered by sacrificial gate 156, by gate spacers 137, and by parts of layer 164 of the second low-permittivity dielectric material may be implemented through layers 142, 144 and a second part of insulating layer 108 comprising bonding interface 152 (see FIG. 9).

An etching of parts of the remaining portions 166 of the first sacrificial layers 144 arranged against the second parts 130 of the first semiconductor nanosheets 104 can then be implemented. This etching is here implemented in such a way that is it selective over the first semiconductor nanosheets 104. This etching forms cavities 168 in which the first inner spacers 128 will be subsequently formed. Further, the duration of implementation of this etching determines the lengths of the cavities 168 along the first semiconductor nanosheets 104, and also the length of the channel formed by these first semiconductor nanosheets 104. It is in particular possible for the length of the channel formed by the first semiconductor nanosheets 104 to be different from that of the channel formed by the second semiconductor nanosheets 106. Like the second semiconductor nanosheets 106, the first semiconductor nanosheets 104 are arranged vertically in line with parts of insulating layer 108. The structure obtained at this stage of the method is shown in FIG. 10.

In the described example of embodiment, a deposition of a layer of the first low-permittivity dielectric material is implemented in such a way that portions of this layer arranged against second parts 130 of the first semiconductor nanosheets 104, that is, in cavities 168, form the first inner spacers 128. Depending on the material used to form the first inner spacers 128, the implemented deposition may be, for example, of ALD, LPCVD, or PECVD type. The first low-permittivity dielectric material used may be identical to or different from that used to form gate spacers 137 and from that used to form the second inner spacers 132.

An isotropic etching can then be implemented to remove the parts of the layer of the first low-permittivity dielectric material located outside cavities 168 and which do not form the first inner spacers 128 (see FIG. 11).

Thus, the various elements present above insulating layer 108, in particular the second semiconductor nanosheets 106 and the second inner spacers 132, are protected during the steps implemented for the forming of the first inner spacers 128, given that the parts of layer 164 located outside cavities 162 are preserved and protect these elements.

In the described example of embodiment, the first source or drain regions 136 are then formed in contact with ends of the second parts 130 of the first semiconductor nanosheets 104 (see FIG. 12). In the described example, these first source or drain regions 136 are formed by implementing an epitaxy. This epitaxy does not affect the second semiconductor nanosheets 106 or portions 160, due to the layer 164 covering them during the implementation of this epitaxy.

In the described example, a dielectric layer intended to form insulating material 139 is then deposited in trenches 154, by covering the first source or drain regions 136. An etching is then implemented to remove the parts of this layer in contact with layer 164. Alternatively, it is possible to implement a thermal oxidation of the first source or drain regions 136. A partial etching of layer 164 is then then partially implemented to only keep the second inner spacers 132 and remove in particular the parts of layer 164 covering the ends of the second semiconductor nanosheets 106 (see FIG. 13).

In the described example, the second source or drain regions 138 are then formed in contact with ends of the second parts 134 of the second semiconductor nanosheets 106. As for the first source or drain regions 136, the second source or drain regions 138 can be obtained by implementing an epitaxy.

A dielectric layer intended to form insulating material 139 can then be deposited into the remaining empty spaces of trenches 154, thus covering the second source or drain regions 138. A chemical-mechanical planarization (CMP) of the material deposited outside trenches 154 may be implemented with a stop on mask 158 (see FIGS. 14 and 15).

In the described example, mask 158 is then removed, for example by implementing a dry or wet etching. Part of the sacrificial gate 156 located at a level above bonding interface 152 may then be removed. In the described example, only the polysilicon or the amorphous silicon of sacrificial gate 156 is removed, the oxide of sacrificial gate 156 being preserved (see FIG. 16).

The oxide of sacrificial gate 156 which is no longer covered by the polysilicon or the amorphous silicon of sacrificial gate 156 may then be etched, after which the remaining polysilicon or amorphous silicon of sacrificial gate 156 may be etched (see FIG. 17).

In the described example of embodiment, the remaining portions 160 of the second sacrificial layers 148 are etched selectively over the second semiconductor nanosheets 106 (see FIG. 18). During this etching, the first semiconductor nanosheets 104 and the remaining portions 166 of the first sacrificial layers 144 are protected by the remaining oxide of the sacrificial gate 156 covering these elements.

A protective layer 170 may then be formed around the second semiconductor nanosheets 106. This protective layer 170 may correspond to a thin semiconductor layer formed by epitaxy, for example comprising the same material as that of the first semiconductor nanosheets 104. As a variant, this protective layer 170 may be formed by implementing a thermal oxidation. The remaining oxide of sacrificial gate 156 may then be etched, and the remaining portions 166 of the first sacrificial layers 144 may then be selectively etched over the first semiconductor nanosheets 104 (FIG. 19).

The first and second gates 110, 114 are then formed. In the described example, gate dielectric 126 is first deposited, for example by the implementation of one of the following depositions: CVD (Chemical Vapor Deposition), LPCVD, APCVD (Atmospheric Pressure Chemical Vapor Deposition), PECVD, ALD. The first metallic material 118 may then be deposited. A wet or dry etching may then be implemented to remove the parts of the first metallic material which are not intended to form the first gate 110. The second metallic material 120 is then deposited to complete the forming of the second gate 114. A CMP lay then be implemented to remove the unwanted parts of the deposited second metallic material 120. The depositions implemented to deposit the first and second metallic materials 118, 120 may be of CVD, LPCVD, APCVD, PECVD, or ALD type. The resulting device 100 corresponds to that previously described in relation with FIG. 1.

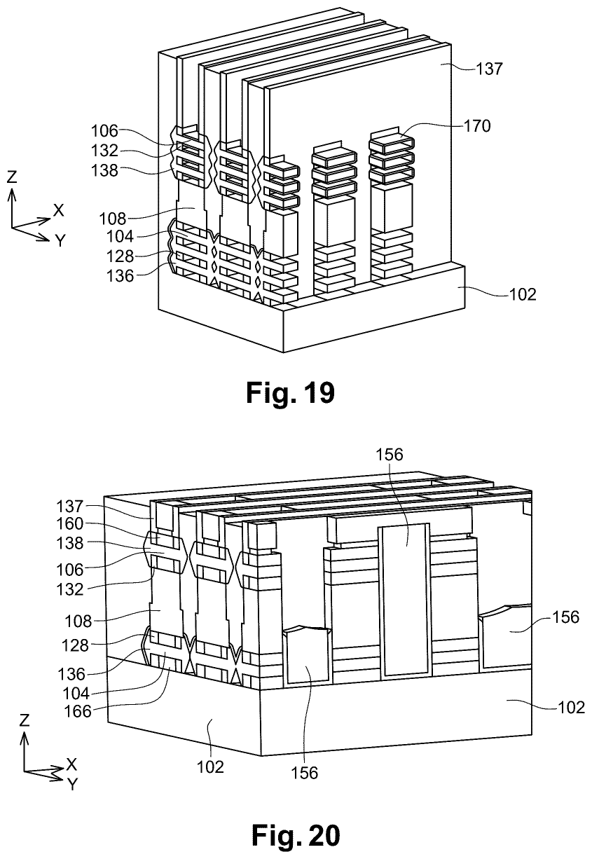

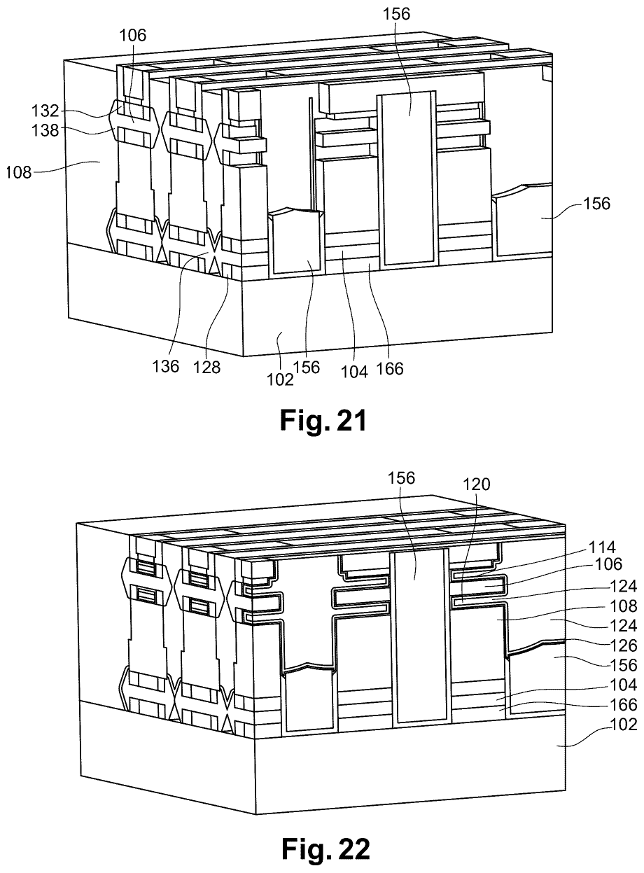

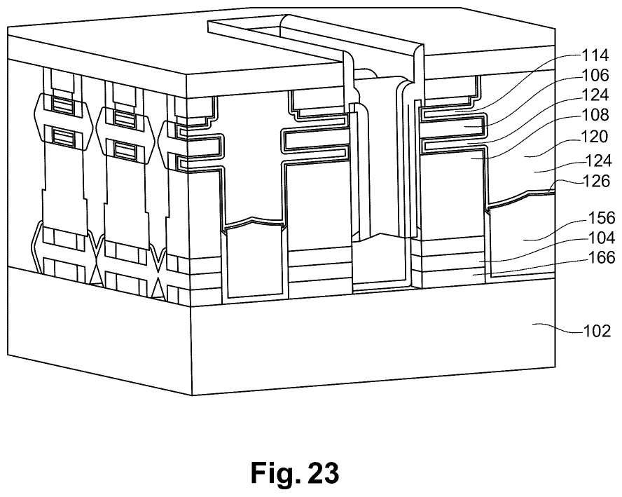

An example of a method of forming the device 100 according to the second embodiment is described hereafter in relation with FIGS. 20 to 23.

Steps similar to those previously described in relation with FIGS. 1 to 15 are first implemented. In this example, the first and second semiconductor nanosheets 104, 106 are formed from a stack of layers comprising a single first semiconductor layer 142 and a single second semiconductor layer 146.

A first part of sacrificial gate 156 is etched so as to form an access to the first part 112 of the first semiconductor nanosheet 104. In the described example, this etching is implemented for first parts of sacrificial gate 156 located between two rows of semiconductor nanosheets 104, 106 and without etching the parts of sacrificial gate 156 located between the rows adjacent thereto (see FIG. 20).

An etching of the remaining portions 160 of the second sacrificial layers 148 selectively over the second semiconductor nanosheets 106 may be implemented (see FIG. 21). During this etching, the first semiconductor nanosheets 104 and the remaining portions 166 of the first sacrificial layers 144 are protected by the parts of sacrificial gate 156 covering these elements.

The second gate 114 is then formed via the deposition of gate dielectric 126 and of the second metallic material 120, for example identical to those previously described for the first embodiment. A CMP may then be implemented to remove the parts of these materials deposited in excess.

The parts of sacrificial gate 156 occupying the spaces in which the first gate 110 is intended to be formed may then be removed down to the level at which the stack of the first semiconductor nanosheets 104 and the remaining portions 166 are located. The insulating portions 135 can then be formed, and then the last remaining parts of sacrificial gate 156 may be etched (see FIG. 23).

In the described example of embodiment, the first gate 110 is then formed via the deposition of gate dielectric 126 and the second metallic material 120, completed by a CMP. The resulting device 100 corresponds to that shown in FIG. 2.

In the various described examples, examples of implementation of etching of the low permittivity dielectric materials are given in document US 2013/252430 A1 and may be used in the above-described method.

In the various examples and embodiments, insulating layer 108 is arranged opposite all the surfaces of the first and second semiconductor nanosheets 104, 106 facing insulating layer 108, which enables to significantly decrease the parasitic capacitances within device 100, and thus to improve the performance of device 100. The obtaining of such a feature is for example possible when insulating layer 108 is obtained by rigidly connecting, for example by bonding, the two insulating layers each present on one of the two stacks of semiconductor nanosheets, and the parts of this insulating layer located vertically in line with the semiconductor nanosheets are preserved until the end of the forming of device 100.

Alternatively, the first internal spacers 128 may be produced before the second spacers 132. In this case, no elements above the insulating layer 108 need to be protected.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. For example, the nature of the implemented depositions and etchings can be chosen as a function, in particular, of the material(s) to be deposited or etched.

1. Device with complementary field-effect transistors, comprising:
a substrate;
at least one first semiconductor nanosheet and at least one second semiconductor nanosheet, the first semiconductor nanosheet being arranged between the second semiconductor nanosheet and the substrate;
an insulating layer arranged between the first and second semiconductor nanosheets;
a first gate arranged around a first part of the first semiconductor nanosheet, and a second gate arranged around a first part of the second semiconductor nanosheet;
first inner spacers arranged against second parts of the first semiconductor nanosheet, between which the first part of the first semiconductor nanosheet is arranged, and
second inner spacers arranged against second parts of the second semiconductor nanosheet, between which the first part of the second semiconductor nanosheet is arranged;
wherein the first and second inner spacers respectively comprise first and second low-permittivity dielectric materials, the first and second dielectric materials being different from each other;
and wherein the insulating layer is arranged opposite all the surfaces of the first and second semiconductor nanosheets located opposite the insulating layer.

2. Device according to claim 1, wherein the first and second semiconductor nanosheets respectively comprise first and second semiconductor materials having crystalline orientations different from each other.

3. Device according to claim 1, wherein the first and second gates respectively comprise first and second metallic materials different from each other.

4. Device according to claim 1, wherein at least part of the first gate is in contact with at least part of the second gate, or wherein the first and second gates are dissociated and insulated from each other.

5. Device according to claim 4, wherein, when the first and second gates are dissociated and insulated from each other, each of the first and second gates is comb-shaped.

6. Method of manufacturing a device with complementary field-effect transistors, comprising at least:
the forming of a structure comprising at least one substrate, first and second semiconductor nanosheets, the first semiconductor nanosheet being arranged between the second semiconductor nanosheet and the substrate, and an insulating layer arranged between the first and second semiconductor nanosheets;
the forming of first inner spacers arranged against second parts of the first semiconductor nanosheet, and of second inner spacers arranged against second parts of the second semiconductor nanosheet, the first and second inner spacers respectively comprising first and second low-permittivity dielectric materials, the first and second dielectric materials being different from each other, and such that the first inner spacers are formed before or after the second inner spacers;
the forming of a first gate around a first part of the first semiconductor nanosheet arranged between the second parts of the first semiconductor nanosheet, and of a second gate around a first part of the second semiconductor nanosheet arranged between the second parts of the second semiconductor nanosheet;
wherein, at the end of these steps, the insulating layer is arranged opposite all the surfaces of the first and second semiconductor nanosheets facing the insulating layer;
and wherein the forming of the structure comprises at least:
the forming of a first stack of layers comprising at least one first semiconductor layer arranged between two first sacrificial layers of a material capable of being selectively etched over the first semiconductor layer, and comprising a first dielectric layer;
the forming of a second stack of layers comprising at least one second semiconductor layer arranged between two second sacrificial layers of a material capable of being selectively etched over the second semiconductor layer, and comprising a second dielectric layer;
the bonding of the first and second dielectric layers to each other and forming the insulating layer together.

7. Method according to claim 6, wherein the forming of the structure further comprises, after the bonding of the first and second dielectric layers to each other, an etching of at least one trench implemented through the first and second stacks of layers and the insulating layer.

8. Method according to claim 7, wherein the forming of the second inner spacers comprises at least:
the forming of a sacrificial gate in the trench and on remaining portions of the structure obtained at the end of the etching of the trench, then the forming of gate spacers around the sacrificial gate, then
the etching of parts of the remaining portions of the structure not covered by the sacrificial gate and the gate spacers, through the layers of the second stack and a first part of the insulating layer without crossing a bonding interface between the first and second dielectric layers, then
the etching of parts of remaining portions of the second sacrificial layers arranged against the second parts of the second semiconductor nanosheet, then
the forming of a layer of the second low-permittivity dielectric material such that portions of this layer arranged against second parts of the second semiconductor nanosheet form the second inner spacers.

9. Method according to claim 8, wherein the forming of the first inner spacers comprises at least, after the forming of the layer of the second low permittivity dielectric material:
the etching of parts of the remaining portions of the structure not covered by the sacrificial gate, the gate spacers, and by parts of the layer of the second low-permittivity dielectric material which rest on a second part of the insulating layer comprising the bonding interface and which cover the ends of the second parts of the second semiconductor nanosheet, through the layers of the first stack and the second part of the insulating layer, then
the etching of parts of remaining portions of the first sacrificial layers arranged against the second parts of the first semiconductor nanosheet, then the forming of a layer of the first low-permittivity dielectric material in such a way that portions of this layer arranged against second parts of the first semiconductor nanosheet form the first inner spacers.

10. Method according to claim 9, further comprising, between the forming of the first and second inner spacers and the forming of the first and second gates:
the forming of first source or drain regions against ends of second the parts of the first semiconductor nanosheet, then
the removal of the parts of the layer of the second low-permittivity dielectric material covering the ends of the second parts of the second semiconductor nanosheet, then
the forming of second source or drain regions against ends of second parts of the second semiconductor nanosheet.

11. Method according to claim 10, wherein the forming of the first and second source or drain regions each comprise the implementation of an epitaxy, and further comprising, between the forming of the first and second source or drain regions, a deposition of insulating material covering at least the first source and drain regions.

12. Method according to claim 9, further comprising, between the forming of the first and second inner spacers and the forming of the first and second gates or during the forming of the first and second gates, an etching of the remaining portions of the first and second sacrificial layers.

13. Method according to claim 8, wherein the forming of the first and second gates comprises an etching of the sacrificial gate, followed by successive depositions of at least one first metallic material forming the first gate and of at least one second metallic material different from the first metallic material and forming the second gate, and such that at least part of the first gate is in contact with at least part of the second gate.

14. Method according to claim 6, wherein the forming of the first and second gates comprises:
an etching of a first part of the sacrificial gate so as to form an access to the first part of the second semiconductor nanosheet, then
a deposition of materials forming the second gate, then
an etching of a second part of the sacrificial gate so as to form an access to the first part of the first semiconductor nanosheet, then
a deposition of materials forming the first gate such that the first and second gates are dissociated and insulated from each other.
